(19) United States
(12) Patent Application Publication
(10) Pub. No.: US 2026/0268954 A1
(43) Pub. Date: Sep. 10, 2026

(54) STORAGE DEVICE

(71) Applicant: Kioxia Corporation, Tokyo (JP)

(72) Inventors: Shogo ITAI, Yokohama (JP); Hiroaki MAEKAWA, Yokohama (JP)

(73) Assignee: Kioxia Corporation, Tokyo (JP)

(21) Appl. No.: 19/325,564

(22) Filed: Sep. 11, 2025

(30) Foreign Application Priority Data
Mar. 5, 2025 (JP) 2025-034891

(51) Int. Cl. G11C 11/16

(52) U.S. Cl. CPC G11C 11/1697; G11C 11/1673

(57) ABSTRACT

According to one embodiment, a memory cell includes a variable resistance element and a switching element connected to the variable resistance element. A first wiring is connected to a first end of the memory cell. A second wiring is connected to a second end of the memory cell. A comparison circuit is connected to a third wiring and a fourth wiring. A first switch is located between the first wiring and the third wiring. A second switch is located between the first wiring and the fourth wiring. A control circuit is configured to cause a first current to flow between the first wiring and the second wiring over a first time period, turn on the first switch over a second time period during the first time period, and turn on the second switch over a third time period after the second time period and during the first period of time.

### CROSS-REFERENCE TO RELATED APPLICATION

This application is based upon and claims the benefit of priority from Japanese Patent Application No. 2025-034891, filed Mar. 5, 2025, the entire contents of which are incorporated herein by reference.

### FIELD

Embodiments described herein relate generally to a storage device.

### BACKGROUND

A storage device that stores data by using the resistance state of an element is known.

### BRIEF DESCRIPTION OF THE DRAWINGS

FIG. 1 shows components of a storage device of a first embodiment and the connections of the components.

FIG. 2 is a circuit diagram of a memory cell array of the storage device of the first embodiment.

FIG. 3 is a perspective view of a part of the memory cell array of the storage device of the first embodiment.

FIG. 4 shows an example of a section of the structure of a memory cell of the storage device of the first embodiment.

FIG. 5 shows functional blocks and components of a part of the storage device of the first embodiment.

FIG. 6 shows components of a reading circuit of the storage device of the first embodiment and an example of the connections of the components.

FIG. 7 shows components of a writing circuit of the storage device of the first embodiment and an example of the connections of the components.

FIG. 8 shows the components of the writing circuit and reading circuit of the storage device of the first embodiment and the connections of the components.

FIG. 9 shows components of a write driver of the storage device of the first embodiment and the connections of the components.

FIG. 10 shows potentials of some signals and wirings over time while data are read out from the storage device of the first embodiment.

### DETAILED DESCRIPTION

A storage device operating at high speed is provided.

In general, according to one embodiment, a storage device includes a memory cell, a first wiring, a second wiring, a third wiring, a fourth wiring, a comparison circuit connected to the third wiring and the fourth wiring, a first switch between the first wiring and the third wiring, and a second switch between the first wiring and the fourth wiring. The memory cell includes a variable resistance element and a switching element connected to the variable resistance element. The first wiring is connected to a first end of the memory cell. The second wiring is connected to a second end of the memory cell. The comparison circuit is connected to the third wiring and the fourth wiring. The first switch is located between the first wiring and the third wiring. The second switch is located between the first wiring and the fourth wiring. A first current is caused to flow between the first wiring and the second wiring over a first period of time, the first switch is turned on over a second period of time during the first period of time, and the second switch is turned on over a third period of time after the second period of time during the first period of time.

Hereinafter, embodiments will be described with reference to the drawings. In one embodiment or different embodiments, a plurality of components having substantially the same functions and configurations may have additional numbers or letters added to the ends of reference signs in order to distinguish them from one another. In embodiments following a described embodiment, differences from the described embodiment will be mainly described. All descriptions of one embodiment also apply to descriptions of another embodiment, unless expressly or obviously excluded.

In the present specification and claims, a first element being “connected” to another second element includes the first element being connected to the second element directly or via an element that is always or selectively conductive.

Hereinafter, a three-dimensional Cartesian coordinate system is used to describe the embodiments. The direction of an x-axis is referred to as X-direction. A direction opposite to the X-direction is referred to as −X-direction. The direction of a y-axis is referred to as Y-direction. A direction opposite to the Y-direction is referred to as −Y-direction. The direction of a z-axis is referred to as Z-direction, and an upward direction indicates the Z-direction. A direction opposite to the Z-direction is referred to as −Z-direction.

### 1. First Embodiment

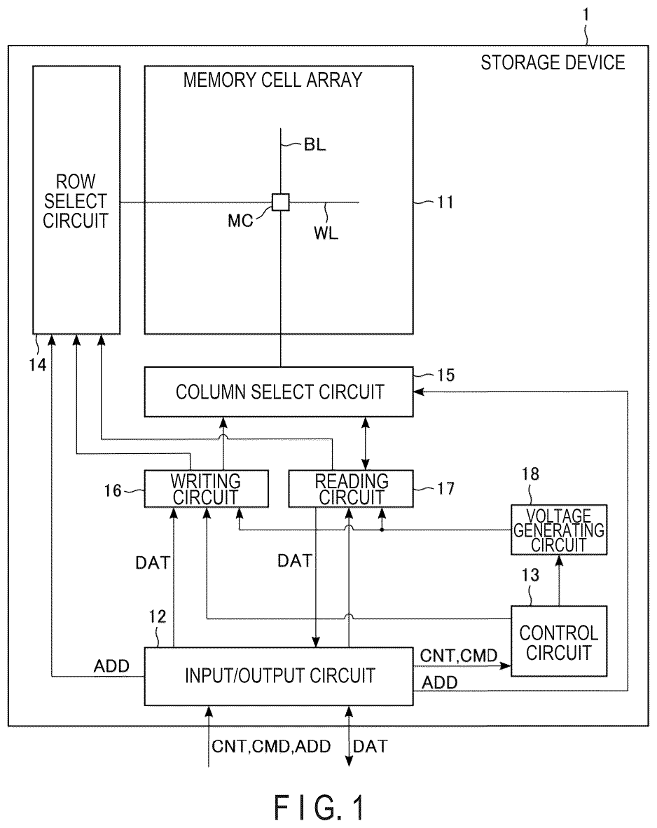

FIG. 1 shows functional blocks of a storage device of a first embodiment. A storage device 1 is a magnetic storage device for storing data using a stacked body of a magnetic material exhibiting dynamically variable resistance. As shown in FIG. 1, the storage device 1 includes a memory cell array 11, an input/output circuit 12, a control circuit 13, a row select circuit 14, a column select circuit 15, a writing circuit 16, a reading circuit 17, and a voltage generating circuit 18.

The memory cell array 11 is a set of a plurality of arranged memory cells MC. The memory cells MC can store data in a non-volatile manner. A plurality of word lines WL and a plurality of bit lines BL are located in the memory cell array 11. Each memory cell MC is connected to one word line WL and one bit line BL. The word lines WL are associated with rows. The bit lines BL are associated with columns. One memory cell MC is specified by selecting one row and one column. In the following description, the terms “word line” and “bit line” are names used simply to distinguish two types of wirings from each other, and may be referred to by the opposite names.

The input/output circuit 12 is a circuit for inputting and outputting data and signals. The input/output circuit 12 receives a control signal CNT, a command CMD, address information ADD, and data DAT from the outside of the storage device 1, for example, from a memory controller. The input/output circuit 12 outputs data DAT. When data is written into the storage device 1, the data DAT means writing data. When data is read out from the storage device 1, the data DAT means reading data.

The voltage generating circuit 18 is a circuit for generating voltages of various magnitudes from voltages received from the outside of the storage device 1. The voltages received from the outside include a power supply voltage VDD and a ground voltage VSS. The voltage generating circuit 18 outputs a voltage of a certain magnitude to be used for data reading. The voltage generating circuit 18 outputs a voltage of a certain magnitude to be used for data writing.

The writing circuit 16 is a circuit for controlling writing of data into the memory cells MC. The writing circuit 16 receives writing data DAT from the input/output circuit 12 and receives a voltage for data writing from the voltage generating circuit 18. The writing circuit 16 outputs a voltage and a current to be used for data writing based on the control of the control circuit 13 and the writing data DAT.

The reading circuit 17 is a circuit for controlling reading of data from the memory cells MC. The reading circuit 17 receives a voltage for data reading from the voltage generating circuit 18. The reading circuit 17 determines data stored in a memory cell MC using the voltage used for data reading based on the control of the control circuit 13. The determined data is supplied to the input/output circuit 12 as reading data DAT. The reading circuit 17 includes a sense amplifier.

The row select circuit 14 is a circuit for selecting a row of memory cells MC. The row select circuit 14 receives address information ADD from the input/output circuit 12. The row select circuit 14 receives a voltage for data writing from the writing circuit 16. The row select circuit 14 receives a voltage for data reading from the reading circuit 17. During data writing, the row select circuit 14 causes one or more word lines WL associated with a row specified by the received address information ADD to fall into a selected state by using the voltage for data writing. During data reading, the row select circuit 14 causes one or more word lines WL associated with a row specified by the received address information ADD to fall into a selected state by using the voltage for data reading.

The column select circuit 15 is a circuit for selecting a column of memory cells MC. The column select circuit 15 receives address information ADD from the input/output circuit 12. The column select circuit 15 receives a voltage for data writing from the writing circuit 16. The column select circuit 15 receives a voltage for data reading from the reading circuit 17. During data writing, the column select circuit 15 causes one or more bit lines BL associated with a column specified by the received address information ADD to fall into a selected state by using the voltage for data writing. During data reading, the column select circuit 15 causes one or more bit lines BL associated with a column specified by the received address information ADD to fall into a selected state by using the voltage for data reading.

The control circuit 13 is a circuit for controlling the operation of the storage device 1. The control circuit 13 receives a control signal CNT and a command CMD from the input/output circuit 12. The control circuit 13 controls the writing circuit 16 and the reading circuit 17 based on the control indicated by the control signal CNT and the command CMD. Specifically, the control circuit 13 controls the writing circuit 16 to supply the voltage received by the writing circuit 16 from the voltage generating circuit 18 to the row select circuit 14 and the column select circuit 15 during writing of data into the memory cell MC. The control circuit 13 controls the reading circuit 17 to supply the voltage received by the reading circuit 17 from the voltage generating circuit 18 to the row select circuit 14 and the column select circuit 15 during reading of data from the memory cell MC.

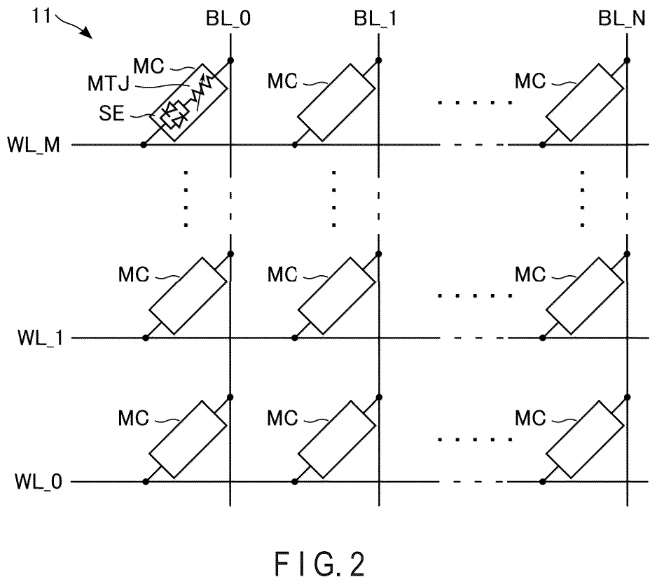

FIG. 2 is a circuit diagram of the memory cell array of the storage device of the first embodiment. As shown in FIG. 2, M+1 (M represents a positive integer) word lines WL (WL_0, WL_1, . . . , WL_M) and N+1 (N represents a positive integer) bit lines BL (BL_0, BL_1, . . . , BL_N) are located in the memory cell array 11.

Each memory cell MC is connected to one word line WL and one bit line BL. Each memory cell MC stores data using a dynamically variable resistance, and includes a variable resistance element. The variable resistance element is an element that can be switched between a low-resistance state and a high-resistance state based on an applied voltage. The following description is based on an example in which the variable resistance element is an MTJ element described later. Another example of the variable resistance element includes a phase change element.

Each memory cell MC includes one MTJ element MTJ and one switching element SE. In each memory cell MC, the MTJ element MTJ and the switching element SE are connected in series to each other. The switching element SE of each memory cell MC is connected to one word line WL. The MTJ element MTJ of each memory cell MC is connected to one bit line BL. Each bit line BL may serve as a first wiring and is connected to a first end of the memory cell MC, i.e., the MTJ element MTJ, and each word line may serve as a second wiring and is connected to a second end of the memory cell, i.e., the switching element.

The MTJ element MTJ is an element that exhibits a tunnel magnetoresistance effect and includes, for example, a magnetic tunnel junction (MTJ). The MTJ element MTJ is also called a magnetoresistance effect element MTJ. The MTJ element MTJ is a variable resistance element that can be switched between a low-resistance state and a high-resistance state. The MTJ element MTJ can store data of one bit by utilizing the difference between the two resistance states. In one example, the MTJ element MTJ stores “0” data by the low-resistance state, and stores “1” data by the high-resistance state. The following description is based on this example.

The switching element SE is an element for electrically connecting or disconnecting both ends of itself. The switching element SE has two terminals. When the voltage applied between the two terminals of the switching element SE is less than a certain first threshold value, the switching element SE is in the high-resistance state, for example, it is in an electrically non-conductive state (OFF-state). When the voltage applied between the two terminals increases and becomes equal to or more than the first threshold value, the switching element SE falls into the low-resistance state, for example, an electrically conductive state (ON-state). When the voltage applied between the two terminals of the switching element SE in the low-resistance state decreases and becomes equal to or less than a second threshold value, the switching element SE falls into the high-resistance state. The switching element SE has a switching function between the high-resistance state and the low-resistance state based on the magnitude of the voltage applied in such a first direction as described above, and also has the same switching function in a second direction opposite to the first direction. In other words, the switching element SE is a bidirectional switching element. When the voltage applied between the two terminals is equal to or more than a threshold voltage Vth in either the first or second direction, the switching element SE falls into the ON-state. When the voltage applied between the two terminals is less than the threshold voltage Vth in either the first or second direction, the switching element SE falls into the OFF-state. Depending on whether the switching element SE falls into the ON-state or the OFF-state, it is possible to control whether or not a current is supplied to the MTJ element MTJ connected to the switching element SE, i.e., whether the MTJ element MTJ is selected or not.

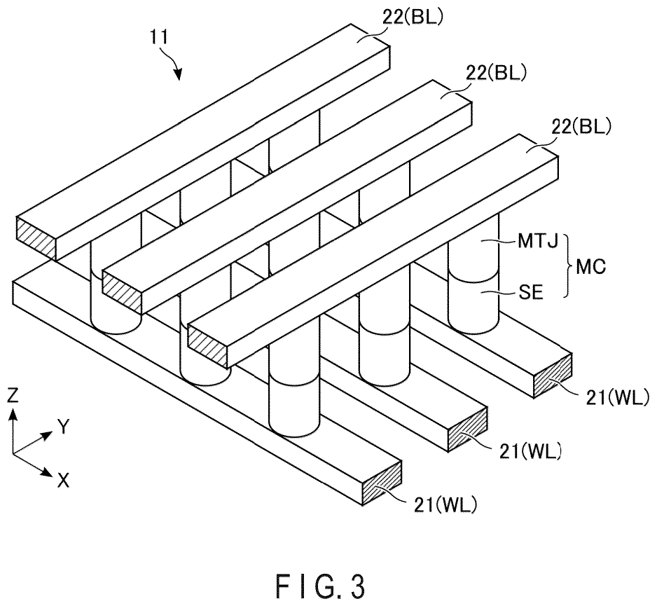

FIG. 3 is a perspective view of a part of the memory cell array of the storage device of the first embodiment. As shown in FIG. 3, a plurality of conductors 21 and a plurality of conductors 22 are provided.

The conductors 21 have a linear shape, extend in the X-direction, and are arranged side by side in the Y-direction. Each conductor 21 functions as one word line WL.

The conductors 22 are located to be apart from the conductors 21 in the Z direction. The conductors 22 have a linear shape, extend in the Y-direction, and are arranged side by side in the X-direction. Each conductor 22 functions as one bit line BL.

One memory cell MC is provided at each intersection between the conductor 21 and the conductor 22. Each memory cell MC includes a structure functioning as a switching element SE and a structure functioning as an MTJ element MTJ. The structure functioning as the switching element SE and the structure functioning as the MTJ element MTJ each include one or more layers. In one example, the structure functioning as the MTJ element MTJ is located on the upper surface of the structure functioning as the switching element SE. The lower surface of the memory cell MC is in contact with the upper surface of one conductor 21. The upper surface of the memory cell MC is in contact with the lower surface of one conductor 22.

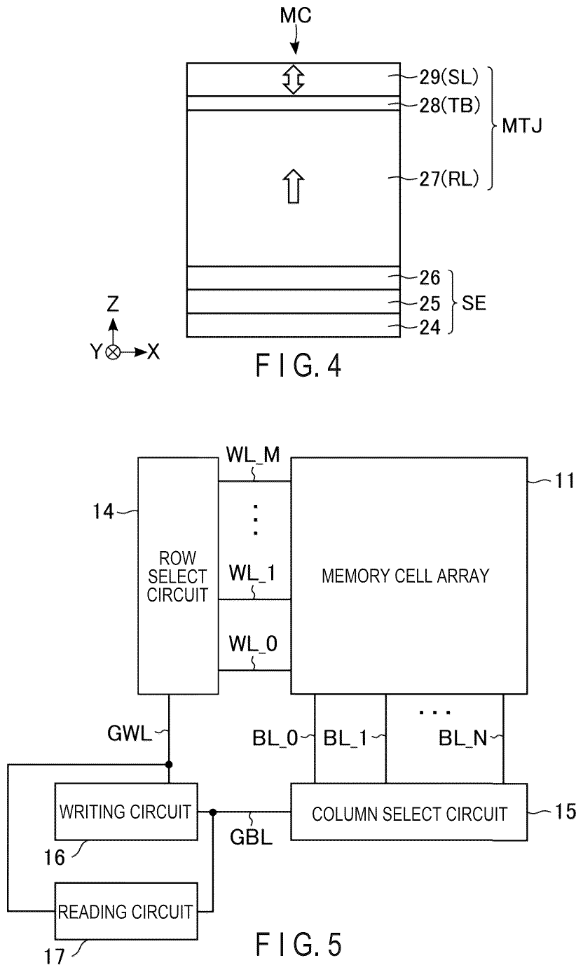

FIG. 4 shows an example of a section of the structure of the memory cell of the storage device of the first embodiment. The switching element SE includes a variable resistance material 25. The variable resistance material 25 is a material that exhibits a dynamically variable resistance, and has, for example, a layer-like shape. The variable resistance material 25 is an interterminal switching element, and a first terminal of two terminals is one of the upper and lower surfaces of the variable resistance material 25, and a second terminal of the two terminals is the other of the upper and lower surfaces of the variable resistance material 25. When a voltage applied between the two terminals is less than a certain threshold voltage, the variable resistance material falls into a “high-resistance” state, for example, an electrically non-conductive state. When the voltage applied between the two terminals increases and becomes equal to or more than the threshold voltage, the variable resistance material falls into a “low-resistance” state, for example, an electrically conductive state. When the voltage applied between the two terminals of the variable resistance material 25 in the low-resistance state drops to be less than the threshold voltage, the variable resistance material falls into a high-resistance state.

In one example, the variable resistance material 25 includes an insulator and a dopant introduced into the insulator by ion implantation. The insulator includes, for example, an oxide, such as SiO₂ or a material that substantially consists of SiO₂. Examples of dopant include arsenic (As), germanium (Ge), boron (B), aluminum (Al), indium (In), phosphorus (P), and antimony (Sb). The phrase “substantially consist of (or composed of)” and similar phrases mean that a component “substantially consists of” may contain unintentional impurities.

The switching element SE may further include a lower electrode 24 and an upper electrode 26. FIG. 4 shows such an example. The variable resistance material 25 is located on the upper surface of the lower electrode 24, and the upper electrode 26 is located on the upper surface of the variable resistance material 25.

The MTJ element MTJ includes a ferromagnetic layer 27, an insulating layer 28, and a ferromagnetic layer 29. As an example, as shown in FIG. 4, the insulating layer 28 is located on the upper surface of the ferromagnetic layer 27, and the ferromagnetic layer 29 is located on the upper surface of the insulating layer 28.

The ferromagnetic layer 27 is a layer of a material exhibiting ferromagnetism. The ferromagnetic layer 27 has an easy axis of magnetization along a direction penetrating through the interfaces of the ferromagnetic layer 27, the insulating layer 28, and the ferromagnetic layer 29, and in one example, has an easy axis of magnetization at an angle of 45° or more and 90° or less with respect to the interfaces, and in one example, has an easy axis of magnetization along a direction perpendicular to the interfaces. The magnetization direction of the ferromagnetic layer 27 is unchanged even when data is read out from and written into the memory cell MC. The ferromagnetic layer 27 can function as a so-called reference layer RL. The ferromagnetic layer 27 may include a plurality of layers. Hereinafter, the ferromagnetic layer 27 may be referred to as a reference layer RL.

The insulating layer 28 is a layer of an insulator. The insulating layer 28 contains, for example, magnesium oxide (MgO) or is substantially composed of MgO, and functions as a so-called tunnel barrier (TB).

The ferromagnetic layer 29 is a layer of a material exhibiting ferromagnetism. The ferromagnetic layer 29 includes, for example, cobalt iron boron (CoFeB) or iron boride (FeB), or is substantially composed of CoFeB or FeB. The ferromagnetic layer 29 has an easy axis of magnetization along a direction penetrating through the interfaces of the ferromagnetic layer 27, the insulating layer 28, and the ferromagnetic layer 29, and in one example, has an easy axis of magnetization at an angle of 45° or more and 90° or less with respect to the interfaces, and in one example, has an easy axis of magnetization along a direction perpendicular to the interfaces. The magnetization direction of the ferromagnetic layer 29 is changeable by data writing into the memory cell MC, and the ferromagnetic layer 29 can function as a so-called storage layer (SL). Hereinafter, the ferromagnetic layer 29 may be referred to as a storage layer SL.

When the magnetization direction of the storage layer SL is parallel to the magnetization direction of the reference layer RL, the MTJ element MTJ has a certain low resistance. The state in which the magnetization direction of the storage layer SL is parallel to the magnetization direction of the reference layer RL is sometimes called a P state.

When the magnetization direction of the storage layer SL is antiparallel to the magnetization direction of the reference layer RL, the MTJ element MTJ has a resistance higher than the resistance when the magnetization directions of the storage layer SL and the reference layer RL are antiparallel to each other. The state in which the magnetization direction of the storage layer SL is antiparallel to the magnetization direction of the reference layer RL is sometimes called an AP state.

When a certain magnitude of P write current Iwp flows from the storage layer SL to the reference layer RL, the magnetization direction of the storage layer SL becomes parallel to the magnetization direction of the reference layer RL. The operation for putting the MTJ element MTJ in a parallel state is sometimes called “P writing”.

When a certain magnitude of AP write current Iwap flows from the reference layer RL to the storage layer SL, the magnetization direction of the storage layer SL becomes antiparallel to the magnetization direction of the reference layer RL. The operation for putting the MTJ element MTJ in an antiparallel state is sometimes called “AP writing”.

The MTJ element MTJ may include additional layers.

FIG. 5 shows functional blocks and components of a part of the storage device of the first embodiment. As shown in FIG. 5, the writing circuit 16 is connected to a global word line GWL and a global bit line GBL. The reading circuit 17 is connected to the global word line GWL and the global bit line GBL.

The global word line GWL is connected to the row select circuit 14. The row select circuit 14 connects the global word line GWL to one word line WL specified by address information ADD.

The global bit line GBL is connected to the column select circuit 15. The column select circuit 15 connects the global bit line GBL to one bit line BL specified by address information ADD.

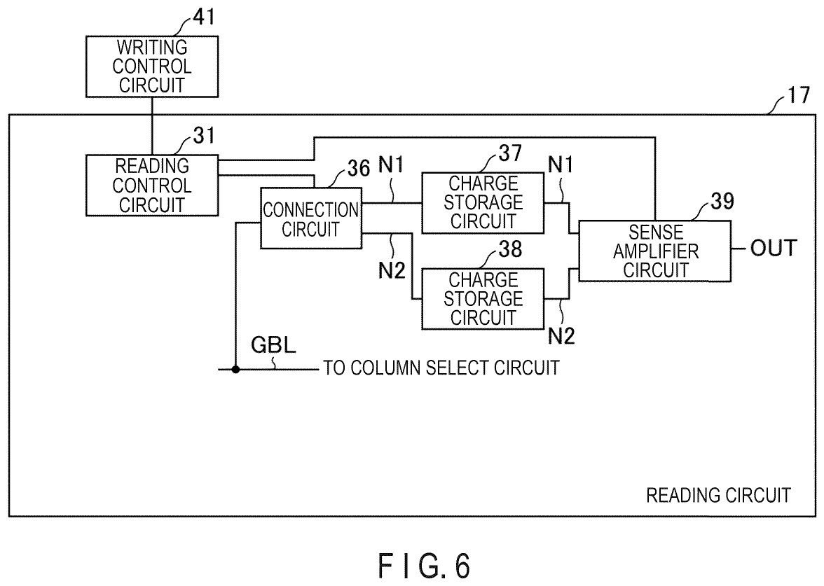

FIG. 6 shows components of the reading circuit of the storage device of the first embodiment and an example of the connections of the components. As shown in FIG. 6, the reading circuit 17 includes a reading control circuit 31, a connection circuit 36, charge storage circuits 37 and 38, and a sense amplifier circuit 39.

The connection circuit 36 is a circuit for connecting the global bit line GBL to dynamically selected one of nodes N1 and N2. The connection circuit 36 operates based on the control by the reading control circuit 31. In one example, the connection circuit 36 includes a switch circuit connected between the global bit line GBL and the node N1, and a switch circuit connected between the global bit line GBL and the node N2. In one example, each switch circuit includes a p-type MOSFET and an n-type MOSFET that are connected in parallel to each other and receive signals of logics inverted to each other at their gates.

The charge storage circuit 37 is a circuit for storing the charge accumulated at the node N1, and thus the potential possessed by the node N1. In one example, the charge storage circuit 37 includes a capacitor connected between the node N1 and a node for receiving the ground voltage VSS.

The charge storage circuit 38 is a circuit for storing the charge accumulated at the node N2, and thus the potential possessed by the node N2. In one example, the charge storage circuit 38 includes a capacitor connected between the node N2 and a node for receiving the ground voltage VSS.

The sense amplifier circuit 39 is a circuit (comparison circuit) for outputting a signal OUT based on the comparison between the potential of the node N1 and the potential of the node N2. When the potential of the node N1 and the potential of the node N2 are substantially the same, that is, the difference between the potential of the node N1 and the potential of the node N2 falls within a certain range, the signal OUT has a level indicating this fact. When the potential of the node N1 and the potential of the node N2 are different from each other, that is, the difference between the potential of the node N1 and the potential of the node N2 gets out of the certain range, the signal OUT has a level indicating this fact.

The reading control circuit 31 is a circuit for controlling the entire data reading. The data reading uses data writing as described below. During the data writing used in the data reading, the reading control circuit 31 instructs the writing control circuit 41 to execute necessary data writing. The writing control circuit 41 is included in the writing circuit 16 as described below.

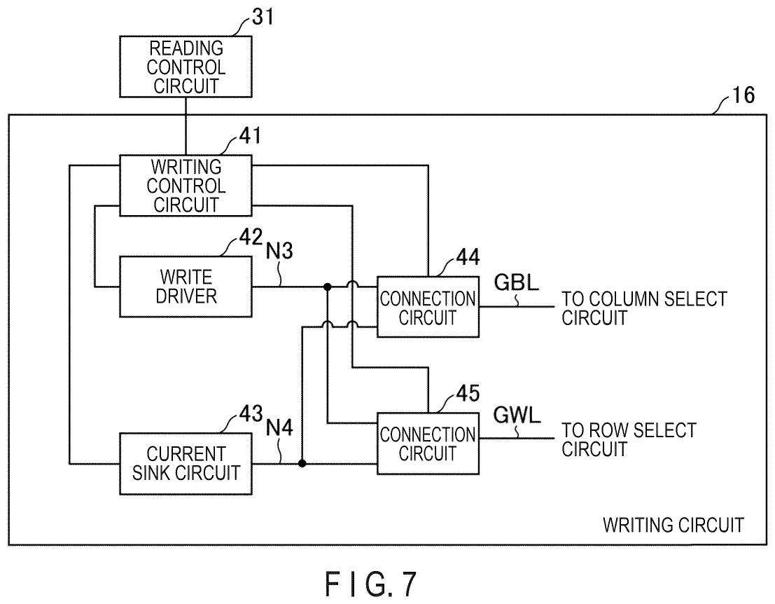

FIG. 7 shows components of the writing circuit of the storage device of the first embodiment, and an example of the connections of the components. As shown in FIG. 7, the writing circuit 16 includes a writing control circuit 41, a write driver 42, a current sink circuit 43, and connection circuits 44 and 45.

The write driver 42 is a circuit for supplying current to a current path including a wiring connected thereto. The write driver 42 is connected to a node N3, and can supply a P write current Iwp and an AP write current Iwap to a current path including the node N3. The write driver 42 includes a constant voltage circuit or a constant current circuit. The write driver 42 operates under the control of the writing control circuit 41. The write driver 42 supplies one of the P write current Iwp and the AP write current Iwap, which is selected based on the control of the writing control circuit 41. The write driver 42 supplies the P write current Iwp or the AP write current Iwap to the node N3 over a dynamically variable period of time based on the control of the writing control circuit 41.

The current sink circuit 43 is a circuit for drawing in current from a wiring connected thereto. The current sink circuit 43 is connected to a node N4 and can draw in current from the node N4. The current sink circuit 43 operates under the control of the writing control circuit 41 and is enabled or disabled under the control of the writing control circuit 41.

The connection circuit 44 is a circuit for connecting dynamically selected one of the nodes N3 and N4 to the global bit line GBL. The connection circuit 44 operates based on the control of the writing control circuit 41. In one example, the connection circuit 44 includes a switch circuit connected between the node N3 and the global bit line GBL, and a switch circuit connected between the node N4 and the global bit line GBL.

The connection circuit 45 is a circuit for connecting dynamically selected one of the nodes N3 and N4 to the global word line GWL. The connection circuit 45 operates based on the control of the writing control circuit 41. In one example, the connection circuit 45 includes a switch circuit connected between the node N3 and the global word line GWL, and a switch circuit connected between the node N4 and the global word line GWL.

The writing control circuit 41 is a circuit for controlling the entire data writing. The writing control circuit 41 connects the node N3 to the global bit line GBL and connects the node N4 to the global word line GWL in order to cause the P write current Iwp to flow. The writing control circuit 41 connects the node N3 to the global word line GWL and connects the node N4 to the global bit line GBL in order to cause the AP write current Iwap to flow.

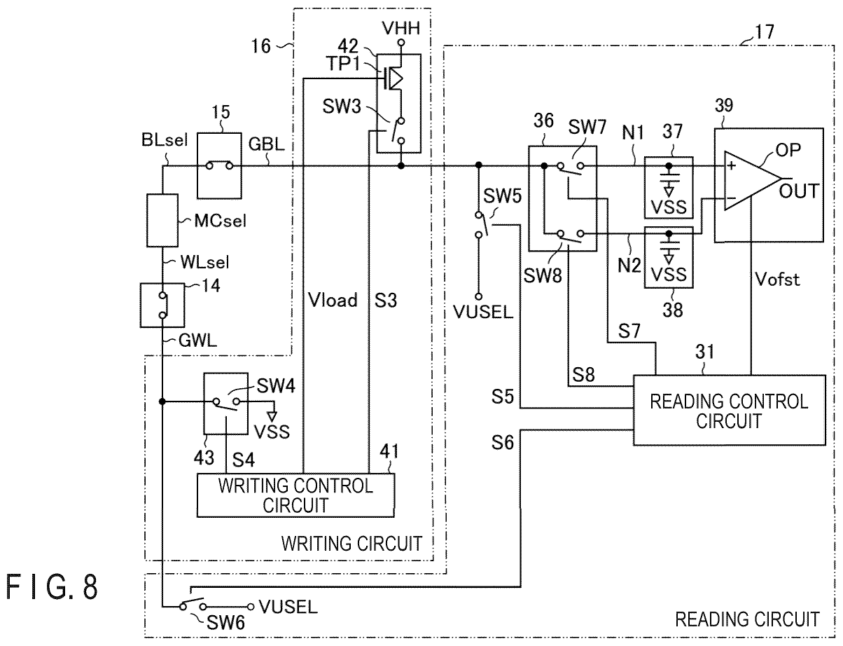

FIG. 8 shows components of the writing circuit and reading circuit of the storage device of the first embodiment and the connections of the components. FIG. 8 shows a state in which a certain memory cell MC is selected as a representative. In other words, as described above with reference to FIG. 1, a state where one word line WL is selected by the row select circuit 14 is set, and a state where one bit line BL is selected by the column select circuit 15 is set. This state is a state where one memory cell MC connected to one word line WL under the selected state and one bit line BL under the selected state is selected, and data is read out from the memory cell MC under the selected state. The word line WL, the bit line BL, and the memory cell MC shown in FIG. 8 are set in a selected state. Hereinafter, the selected memory cell may be referred to as a selected memory cell MCsel. The word line WL under the selected state may be referred to as a selected word line WLsel. The bit line BL under the selected state may be referred to as a selected bit line BLsel. The MTJ element MTJ of the selected memory cell MCsel may be referred to as a selected MTJ element MTJsel. FIG. 8 also shows a state in which the writing circuit 16 can cause a P write current Iwp to flow. FIG. 8 shows a case in which the write driver 42 includes a constant current circuit.

As shown in FIG. 8, the write driver 42 includes a p-type metal oxide semiconductor field effect transistor (MOSFET) TP1 and a switch SW3. The transistor TP1 and the switch SW3 are connected in this order between a node receiving a voltage VHH and the global bit line GBL. In one example, the node receiving the voltage VHH receives the voltage VHH from the voltage generating circuit 18. The voltage VHH is an internal power supply voltage and is higher than the ground voltage VSS. The transistor TP1 receives a voltage Vload of a variable magnitude at its gate. In one example, the voltage Vload is supplied from the writing control circuit 41. The voltage Vload has a magnitude that enables the write driver 42 to cause an AP write current Iwap to flow through the selected memory cell MCsel.

The switch SW3 is a p-type or n-type MOSFET, or p-type and n-type MOSFETs that are connected in parallel and receive complementary signals at their gates. The switch SW3 is in an ON-state while receiving a signal S3 of a certain level, and keeps a state where one end and the other end of the switch SW3 are electrically connected to each other. The switch SW3 is in an OFF-state while receiving a signal S3 of a certain different level, and keeps a state where one end and the other end of the switch SW3 are electrically disconnected from each other. The following description is based on an example in which a level for turning on the switch SW3 is a high level, and a level for turning off the switch SW3 is a low level. The same applies to a switch SWn and a signal Sn where n is an integer of 4 or more. In other words, with respect to the switch SWn, the description on switch SW3 applies likewise to the switch SWn, and with respect to the signal Sn, the description on signal S3 applies likewise to the signal Sn.

The current sink circuit 43 includes a switch SW4. The switch SW4 is connected between the global word line GWL and a node receiving the ground voltage VSS.

The writing control circuit 41 outputs signals S3 and S4.

In one example, the sense amplifier circuit 39 includes an operational amplifier OP. The operational amplifier OP is connected to the node N1 at its non-inverting input. The operational amplifier OP is connected to the node N2 at its inverting input. The sense amplifier circuit 39 receives an offset voltage Vofst. The sense amplifier circuit 39 increases the potential at the inverting input while receiving the offset voltage Vofst.

The reading circuit 17 further includes switches SW5 and SW6. The switch SW5 is connected between the global bit line GBL and a node receiving an unselected voltage VUSEL. The unselected voltage VUSEL is higher than the ground voltage VSS. In one example, the unselected voltage VUSEL is supplied from the voltage generating circuit 18. The switch SW6 is connected between the global word line GWL and a node receiving the unselected voltage VUSEL.

The connection circuit 36 includes switches SW7 and SW8. The switch SW7 is connected between the global bit line GBL and the node N1. The switch SW8 is connected between the global bit line GBL and the node N2. For example, the selected bit line BLsel may be referred to as a ‘first wiring,’ and the selected word line WLsel may be referred to as a ‘second wiring.’ The node N1 may be referred to as a ‘third wiring’ and the node N2 may be referred to as a ‘fourth wiring.’ The switch SW7, which connects the first wiring to the third wiring, may be referred to as a ‘first switch,’ and the switch SW8, which connects the first wiring to the fourth wiring, may be referred to as a ‘second switch.’ The sense amplifier circuit 39 functions as a ‘comparison circuit’ connected to the third and fourth wirings.

The reading control circuit 31 outputs signals S5, S6, S7, and S8.

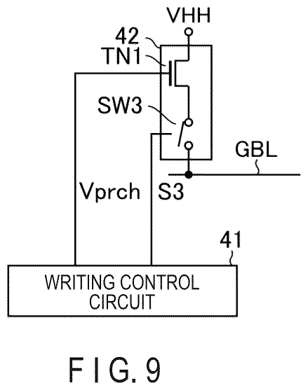

FIG. 9 shows components of the write driver of the storage device of the first embodiment and the connections of the components. FIG. 9 shows a case where the write driver 42 includes a constant voltage circuit. As shown in FIG. 9, the write driver 42 includes an n-type MOSFET TN1 and a switch SW3. The transistor TN1 and the switch SW3 are connected in this order between a node receiving the voltage VHH and the global bit line GBL. The transistor TN1 receives a voltage Vprch of a fixed magnitude at its gate. In one example, the voltage Vload is supplied from the writing control circuit 41. The voltage Vprch has a magnitude that allows the write driver 42 to cause an AP write current Iwap to flow through the selected memory cell M Csel.

### 1.2. Operation

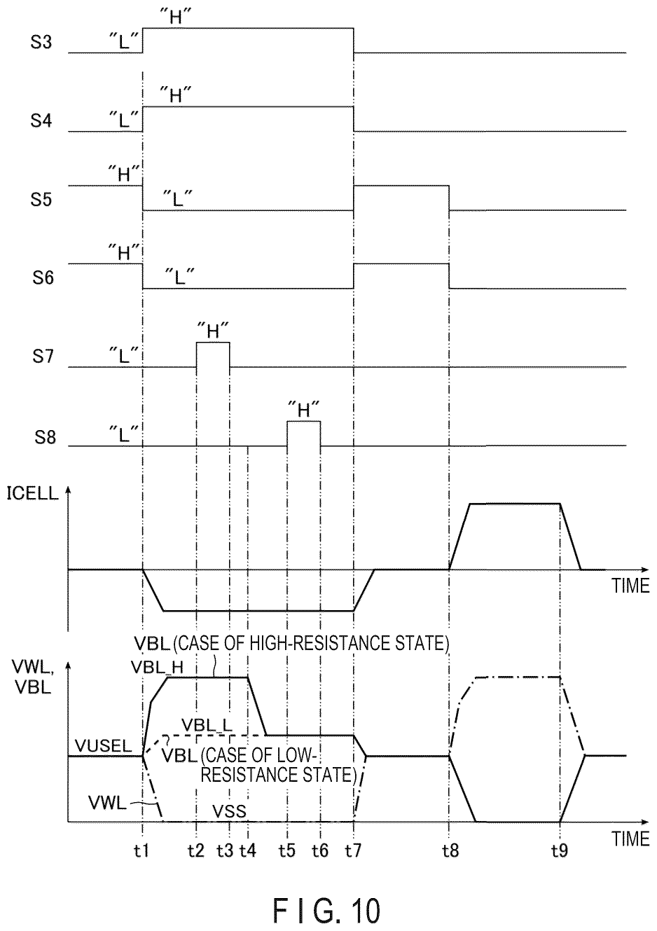

FIG. 10 shows potentials of some signals and wirings over time during data reading of the storage device of the first embodiment.

An operation occurring during a period of time shown in FIG. 10 starts when data reading starts in a state where a selected memory cell MCsel as a data reading target is selected. In one example, the operation occurring during the period of time shown in FIG. 10 is controlled by the reading control circuit 31.

A cell current ICELL is a current that flows through the selected memory cell Mcsel. The cell current ICELL can flow in two directions. The same direction out of the two directions as the direction of the P write current Iwp may be referred to as a negative direction. The same direction out of the two directions as the direction of the AP write current Iwap may be referred to as a positive direction.

At the start time of the operation shown in FIG. 10, the signals S3, S4, S7, and S8 have low levels, and the signals S5 and S6 have high levels. Based on the signal S3 having a low level and the signal S5 having a high level, the global bit line GBL has received the unselected voltage VUSEL, and as a result, the global bit line GBL has a potential VUSEL. Thus, the potential of the selected bit line VBLsel (selected bit line potential VBL) is the potential VUSEL.

Based on the signal S4 having a low level and the signal S5 having a high level, the global word line GWL has received the unselected voltage VUSEL, and as a result, the global word line GWL has the potential VUSEL. Therefore, the potential of the selected word line WLsel (selected word line potential VWL) is the potential VUSEL.

Based on both the selected bit line potential VBL and the selected word line potential VWL having the potential VUSEL, the cell current ICELL does not flow.

Based on the signal S7 having a low level, the switch SW7 is turned off and the node N1 is electrically floating.

Based on the signal S8 having a low level, the switch SW8 is turned off and the node N2 is electrically floating.

At time t1, the levels of the signals S5 and S6 are set to a low level. As a result, the application of the unselected voltage VUSEL to the selected word line WLsel and the selected bit line BLsel is stopped.

At time t1, the levels of the signals S3 and S4 are set to a high level. This operation is instructed to the writing control circuit 41 by the reading control circuit 31, and the writing control circuit 41 which has received the instruction performs the operation. Based on the signals S3 and S4 having a high level, the write driver 42 and the current sink circuit 43 are enabled, and the P write current Iwp flows through the selected memory cell MCsel. In other words, a cell current ICELL in the negative direction which has the same magnitude as the P write current Iwp flows.

The current sink circuit 43 is enabled, whereby the selected word line potential VWL drops from time t1, and then becomes the ground potential VSS.

As the P write current Iwp flows, the selected bit line potential VBL rises from time t1. The selected bit line potential VBL has a magnitude that depends on the resistance state of the selected MTJ element MTJsel.

When the selected MTJ element MTJsel has a low-resistance state, the selected bit line potential VBL has a potential VBL_L. The potential VBL_L is higher than the ground potential VSS, and in one example, it is higher than the potential VUSEL.

When the selected MTJ element MTJsel has a high-resistance state, the selected bit line potential VBL has a potential VBL_H. The potential VBL_H is higher than the potential VBL_L.

At time t2, the signal S7 is set to a high level. As a result, the global bit line GBL is connected to the charge storage circuit 37, and the selected bit line potential VBL is transferred to the charge storage circuit 37. After the potential is transferred, the signal S7 is set to a low level at time t3. As a result, the node N1 is electrically floating, and the selected bit line potential VBL is stored in the charge storage circuit 37. The selected bit line potential VBL from time t2 depends on the data stored in the selected memory cell MCsel at the start time of data reading, that is, the resistance state of the selected MTJ element MTJsel. In other words, at time t2, the selected MTJ element MTJsel has the same resistance state as the resistance state which it had at the start time of data reading. Hereinafter, storing the selected bit line potential VBL from time t2 into the charge storage circuit 37 may be referred to as a first sense.

The P write current Iwp flows from time t1, whereby the selected MTJ element MTJsel is caused to fall into a low-resistance state (P state) at time t4. As a result, the terminal voltage of the selected MTJ element MTJsel drops, and the selected word line potential VWL becomes the potential VBL_L.

When the selected MTJ element MTJsel is in a low-resistance state at the start of data reading, flow of the P write current Iwp also causes the selected MTJ element MTJsel to keep the low-resistance state. Hereinafter, it may be referred to as reference data writing that the selected MTJ element MTJsel is caused to fall into a certain resistance state (low-resistance state) by causing a write current (P write current Iwp) to flow from time t1.

At time t5, the signal S8 is set to a high level. As a result, the global bit line GBL is connected to the charge storage circuit 38, and the selected bit line potential VBL is transferred to the charge storage circuit 38. After the potential is transferred, the signal S8 is set to a low level at time t6. As a result, the node N2 is electrically floating, and the selected bit line potential VBL is stored in the charge storage circuit 38. The selected bit line potential VBL from time t5 is based on the selected memory cell MCsel in a low-resistance state. Hereinafter, storing the selected bit line potential VBL from time t5 into the charge storage circuit 38 may be referred to as a second sense.

At time t7, the signals S3 and S4 are set to a low level. This operation is instructed to the writing control circuit 41 by the reading control circuit 31, and the writing control circuit 41 which has received the instruction performs the operation. Based on the signals S3 and S4 having a low level, the write driver 42 and the current sink circuit 43 are disabled and the flow of the P write current Iwp is stopped. As a result, the cell current ICELL does not flow.

At time t7, the signals S5 and S6 are set to a high level. As a result, the selected bit line potential VBL and the selected word line potential VWL become the potential VUSEL.

At time t7, the sense amplifier circuit 39 is enabled, which causes the sense amplifier circuit 39 to output a signal OUT having a level based on the state of the selected MTJ element MTJsel. The signal OUT has a certain first value (e.g., a low level) when the potential of the node N1 (i.e., the result of the first sense) and the potential of the node N2 (i.e., the result of the second sense) are substantially the same, more specifically, when the difference between the potential of the node N1 and the potential of the node N2 falls within a certain first range. The fact that the potential of the node N1 and the potential of the node N2 are substantially the same indicates that the selected MTJ element MTJsel was in a low-resistance state at the start time of data reading. The signal OUT functions as a signal indicating the data that the selected MTJ element MTJsel had at the start time of data reading.

On the other hand, the signal OUT has a certain second value (e.g., a high level) when the potential of the node N1 and the potential of the node N2 are different from each other, more specifically, when the difference between the potential of the node N1 and the potential of the node N2 does not fall within the first range. The fact that the potential of the node N1 and the potential of the node N2 are different from each other indicates that the selected MTJ element MTJsel was in a high-resistance state at the start time of data reading.

An offset voltage Vofst is supplied while the potential of the node N1 and the potential of the node N2 are being compared with each other.

When the potential of the node N1 and the potential of the node N2 are the same, the data reading is terminated. On the other hand, when the potential of the node N1 and the potential of the node N2 are different from each other, AP writing is performed on the selected memory cell MCsel. In other words, at time t8, the application of the unselected voltage VUSEL to the selected word line WLsel and the selected bit line BLsel is stopped.

At time t8, the AP write current Iwap is caused to flow. This is performed by the reading control circuit 31 instructing the writing control circuit 41 to cause the AP write current Iwap to flow. Specifically, this is performed as follows. Upon receiving the instruction, the writing control circuit 41 controls the connection circuit 44 and the connection circuit 45 to connect the node N3 to the global word line GWL and also connect the node N4 to the global bit line GBL. As a result, the write driver 42 is connected to the selected word line WLsel, and the current sink circuit 43 is connected to the selected bit line BLsel.

Next, the writing control circuit 41 instructs the write driver 42 to cause the AP write current Iwap to flow and also enables the current sink circuit 43. Upon receiving the instruction, the write driver 42 causes the AP write current Iwap to flow through the node N3. In one example, in order to cause the AP write current Iwap to flow, the writing control circuit 41 applies a voltage Vload to the gate of the transistor TP1, the voltage Vload having a magnitude sufficient to cause the AP write current Iwap to flow through the selected memory cell MCsel and sets the signal S1 to a high level.

The current sink circuit 43 is enabled, whereby the selected bit line potential VBL drops from time t8, and then becomes the ground potential VSS.

As the AP write current Iwap flows, the selected word line potential VWL rises from time t8.

At time t9, the flow of the AP write current Iwap is stopped. At time t9, the selected word line potential VWL and the selected bit line potential VBL are set to the potential VUSEL.

### 1.3. Advantage (Effect)

According to the first embodiment, as described below, a storage device that operates at high speed is provided.

Data Reading from a selected memory cell may include acquiring the potential based on the state of the selected memory cell (corresponding to the first sense), writing reference data into the selected memory cell, acquiring the potential based on the state of the selected memory cell (corresponding to the second sense), and comparing the result of the first sense with the result of the second sense, which reduces the variation in the data reading result caused by the variation in the characteristics of the memory cells. Each of the first sense, the reference data writing, and the second sense requires application of a voltage to the selected bit line and the selected word line. Therefore, times for charging and discharging the selected bit line and the selected word line are required in each of the first sense, the reference data writing, and the second sense. This increases the time for data reading and also increases power consumption.

According to the first embodiment, data reading from the selected memory cell MCsel includes causing the P write current Iwp to flow through the selected memory cell MCsel, and performing the first sense and the second sense while the P write current Iwp flows through the selected memory cell MCsel. In other words, the reference data writing and the set of the first sense and the second sense are performed in parallel. Such an operation as described above also makes it possible to perform data reading as in the case the first sense, the reference data writing, and the second sense are performed independently of one another. On the other hand, as can be seen from FIG. 10, each of the selected bit line BLsel and the selected word line WLsel is only charged once and discharged once between times t1 and t7. Therefore, it is possible to perform data reading in a short time and reduce power consumption.

### 1.4. Modification

The reference data writing is not limited to P writing, but it may be AP writing. In this case, during data reading, the write driver 42 is connected to the global word line GWL, and the current sink circuit 43 is connected to the global bit line GBL. From time t1, the writing control circuit 41 controls the write driver 42 and the current sink circuit 43 to cause the AP write current Iwap to flow through the selected memory cell MCsel.

While certain embodiments have been described, these embodiments have been presented by way of example only and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is

1. A storage device comprising:
a memory cell including a variable resistance element and a switching element connected to the variable resistance element;
a first wiring connected to a first end of the memory cell;
a second wiring connected to a second end of the memory cell;
a third wiring;
a fourth wiring;
a comparison circuit connected to the third wiring and the fourth wiring;
a first switch between the first wiring and the third wiring;
a second switch between the first wiring and the fourth wiring; and
a control circuit configured to
cause a first current to flow between the first wiring and the second wiring over a first period of time,
turn on the first switch over a second period of time during the first period of time, and
turn on the second switch over a third period of time after the second period of time during the first period of time.

2. The storage device of claim 1, wherein
the variable resistance element dynamically switches between a first state having a first resistance and a second state having a second resistance, and
the first current has a magnitude that causes the variable resistance element to fall into the first state.

3. The storage device of claim 2, wherein
the second period of time occurs before the variable resistance element in the second state is switched to the first state by the first current.

4. The storage device of claim 3, wherein
the third period of time occurs after the variable resistance element which is in the second state at a start of the first period of time is switched to the first state by the first current.

5. The storage device of claim 4, wherein
the second resistance is higher than the first resistance.

6. The storage device of claim 4, wherein
the second resistance is lower than the first resistance.

7. The storage device of claim 1, wherein
the control circuit is further configured to cause the third wiring to be electrically floating during a period of time of the first period of time excluding the second period of time.

8. The storage device of claim 7, wherein
the control circuit is further configured to cause the fourth wiring to be electrically floating during a period of time of the first period of time excluding the third period of time.

9. The storage device of claim 1, further comprising a constant current circuit for causing the first current to flow.

10. The storage device of claim 1, further comprising a constant voltage circuit for causing the first current to flow.

11. The storage device of claim 1, further comprising:
a first charge storage circuit connected to the third wiring; and
a second charge storage circuit connected to the fourth wiring.

12. The storage device of claim 11, wherein the first charge storage circuit and the second charge storage circuit each include a capacitor.

13. The storage device of claim 1, wherein the variable resistance element is a magnetic tunnel junction (MTJ) element.

14. The storage device of claim 1, wherein the switching element is a bidirectional switching element that enters a conductive state when a voltage across it exceeds a threshold voltage.

15. The storage device of claim 1, wherein the first wiring is a bit line and the second wiring is a word line.

16. The storage device of claim 1, wherein the control circuit is further configured to, in response to an output of the comparison circuit indicating a difference between a potential on the third wiring and a potential on the fourth wiring, cause a second current to flow through the memory cell to restore the variable resistance element to a state it was in prior to the first period of time.

17. A method for reading data from a storage device, the method comprising:
applying a first current to a memory cell through a first wiring and a second wiring during a first time period, the first current having a magnitude sufficient to write the memory cell to a first resistance state;
during the first time period and before the memory cell is written to the first resistance state, connecting the first wiring to a first charge storage node for a second time period to store a first potential;
subsequent to the memory cell being written to the first resistance state and during the first time period, connecting the first wiring to a second charge storage node for a third time period to store a second potential; and
comparing the first potential and the second potential to determine the data stored in the memory cell.

18. The method of claim 17, wherein applying the first current to the memory cell during the first time period includes a single charging event for the first wiring and a single discharging event for the second wiring, and wherein the first current flows continuously through the memory cell between the second time period and the third time period.

19. The method of claim 17, further comprising restoring the memory cell to a second resistance state if the comparison indicates the second resistance state was different from the first resistance state.

20. A storage device, comprising:
a memory cell array including a plurality of memory cells arranged in rows and columns, each memory cell including a variable resistance element;
a plurality of bit lines and a plurality of word lines connected to the memory cells;
a writing circuit configured to supply a write current to a selected memory cell via a selected bit line and a selected word line;
a reading circuit including a first node, a second node, and a comparison circuit configured to compare a potential of the first node with a potential of the second node; and
a control circuit operatively coupled to the writing circuit and the reading circuit, the control circuit configured to perform a read operation by:
controlling the writing circuit to supply the write current to the selected memory cell for a continuous period;
during the continuous period, controlling the reading circuit to first store a potential of the selected bit line on the first node; and
subsequently during the continuous period, controlling the reading circuit to second store the potential of the selected bit line on the second node.
